(19) United States
(12) Patent Application Publication
(10) Pub. No.: US 2008/0238728 A1
(43) Pub. Date: Oct. 2, 2008

(54) ELECTRONIC APPARATUS AND KEY PRESSING DETERMINATION METHOD

(75) Inventor: Hironori Motoe, Ome-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/048,105

(22) Filed: Mar. 13, 2008

(30) Foreign Application Priority Data
Mar. 28, 2007 (JP) 2007-084278

(51) Int. Cl. H03K 17/94; H03M 11/00

(52) U.S. Cl. 341/24

(57) ABSTRACT

According to one embodiment, an electronic apparatus includes a plurality of keys, a monitoring unit which repeatedly monitors states of the plurality of keys at a predetermined period, a setting unit which sets, as a reference value for determining presence/absence of pressing of each of the plurality of keys, the number of pressed states continuously detected by the monitoring unit, and a determination unit which determines that a key is pressed when the number of pressed states continuously detected by the monitoring unit reaches the number of pressed states set by the setting unit.

### CROSS-REFERENCE TO RELATED APPLICATIONS

This application is based upon and claims the benefit of priority from Japanese Patent Application No. 2007-084278, filed Mar. 28, 2007, the entire contents of which are incorporated herein by reference.

### BACKGROUND

1. Field

One embodiment of the present invention relates to a key operation control technique suitably applied to an electronic apparatus such as a notebook computer, personal digital assistant (PDA), or keyboard.

2. Description of the Related Art

In recent years, a variety of battery powered portable electronic apparatuses such as notebook computers and PDAs have been developed. Along with advances in wireless communication infrastructure, users can easily transmit or receive data at remote locations or on the move. Thus a stronger demand for wireless communication has arisen.

Portability of electronic apparatuses of this type is an important factor in determining the product value. These electronic apparatuses have been made smaller and lighter these days. A variety of implementations have been made not to impair operability when the devices are made smaller and lighter (see Jpn. Pat. Appln. KOKAI publication No. 2006-79343).

A portable information terminal described in Jpn. Pat. Appln KOKAI publication No. 2006-79343 proposes a technique for preventing key input errors as much as possible by setting a large operation force for a key arranged at a position where key input errors tend to occur.

Assume a portable electronic apparatus in which a keyboard having a standard key layout is mounted in the main body of the apparatus. Assume also that a high-use-frequency key and a low-use-frequency key are adjacent to each other in accordance with the type of installed operating system and the type of frequently used application program.

It is difficult to assure a given distance between keys using a spacer in a keyboard mounted in a compact main body. A user wants to press a high-use-frequency key, but may often press it together with a low-use-frequency key, or erroneously press the low-use-frequency key.

Under these circumstances, it is possible to apply the technique proposed by Jpn. Pat. Appln. KOKAI publication No. 2006-79343. However, when the hardware measure fixes the setting such that a specific key requires a large operation force, this measure cannot flexibly cope with a change in situation where the high- and low-use-frequency keys are adjacent to each other, depending on changes in types of operating system and frequently used application programs. The measure which sets a large key operation force for a specific key disables use of the conventional standard keyboard, increasing the cost.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view of an electronic apparatus of the first embodiment when viewed from the front side;

FIG. 2 is an exemplary block diagram showing the system arrangement of the electronic apparatus according to the first embodiment;

FIG. 3 is an exemplary view showing a key layout of the keyboard of the electronic apparatus according to the first embodiment;

FIG. 4 is an exemplary view for explaining the principle for causing an EC/KBC of the electronic apparatus according to the first embodiment to monitor the state of each key on the keyboard;

FIG. 5 is an exemplary determination table held by the EC/KBC of the electronic apparatus according to the first embodiment;

FIG. 6 is an exemplary flowchart showing the operation sequence of key pressing determination executed by the EC/KBC of the electronic apparatus according to the first embodiment;

FIG. 7 is an exemplary functional block diagram associated with key inputs of an electronic apparatus according to the second embodiment;

FIG. 8 is an exemplary chart for explaining the principle of outputting a key code by the EC/KBC according to the second embodiment; and

FIG. 9 is an exemplary flowchart showing the operation sequence of key pressing determination executed by the keyboard driver of the electronic apparatus according to the second embodiment.

### DETAILED DESCRIPTION

Various embodiments according to the invention will be described hereinafter with reference to the accompanying drawings. In general, according to one embodiment of the invention, an electronic apparatus includes a plurality of keys, a monitoring unit which repeatedly monitors states of the plurality of keys at a predetermined period, a setting unit which sets, as a reference value for determining presence/absence of pressing of each of the plurality of keys, the number of pressed states continuously detected by the monitoring unit, and a determination unit which determines that a key is pressed when the number of pressed states continuously detected by the monitoring unit reaches the number of pressed states set by the setting unit.

### First Embodiment

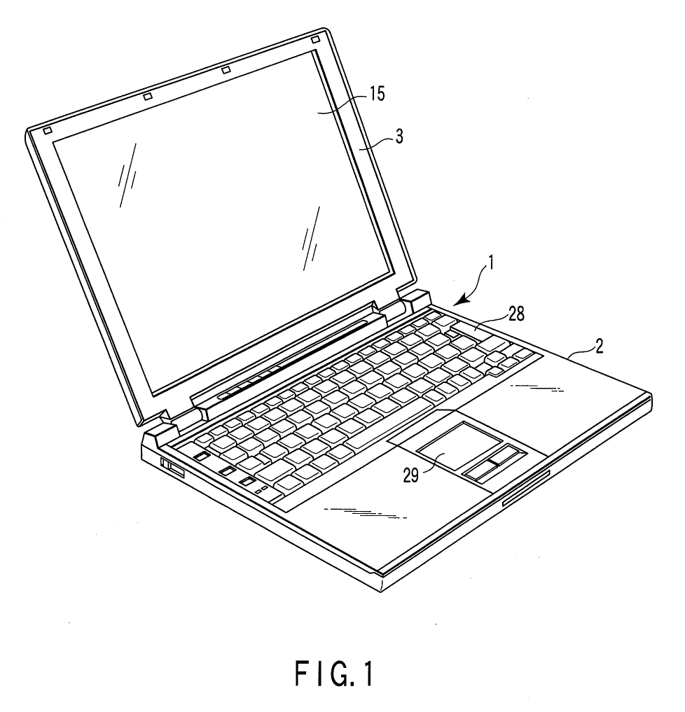

FIG. 1 is an exemplary perspective view of an electronic apparatus of this embodiment in an open state of a display unit when viewed from the front side. A battery-drivable notebook computer 1 implements this electronic apparatus.

The computer 1 comprises a computer main body 2 and display panel 3. The display panel 3 incorporates a display device made up of a liquid crystal display (LCD) 15, and its screen is located at nearly the center of the display panel 3.

The computer main body 2 supports the display panel 3 mounted pivotally between an open position to expose the upper surface of the computer main body 2 and a closed position to cover the upper surface of the computer main body 2. The computer main body 2 has a low-profile box-like housing. A keyboard 28 and touch pad 29 are arranged on the upper surface of the computer main body 2.

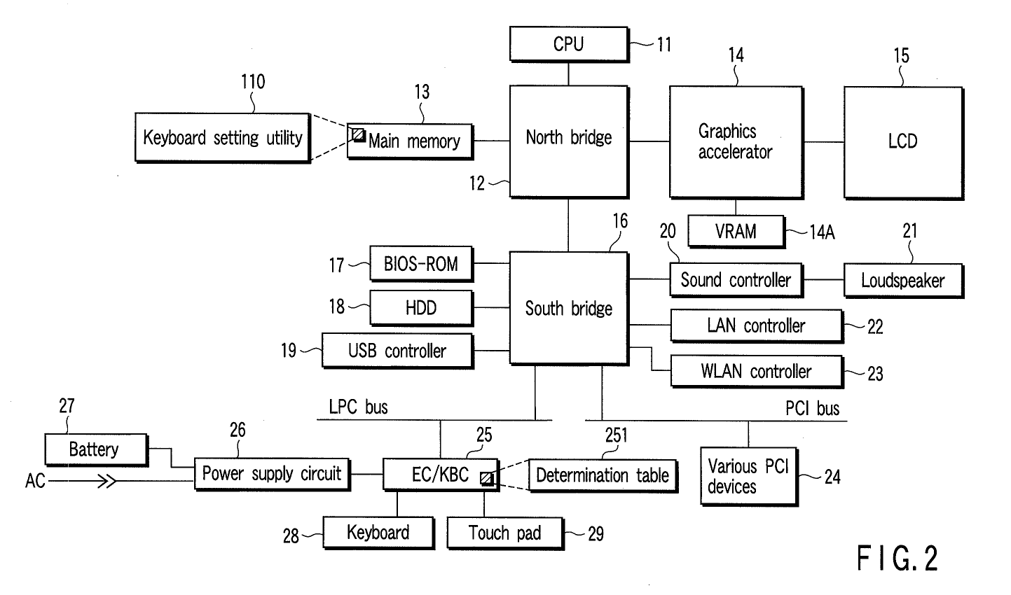

FIG. 2 is an exemplary block diagram showing the system arrangement of the computer 1. As shown in FIG. 2, the computer 1 comprises a CPU 11, north bridge 12, main memory 13, graphics accelerator 14, VRAM 14A, south bridge 16, BIOS-ROM 17, HDD 18, USB controller 19, sound controller 20, loudspeaker 21, LAN controller 22, WLAN controller 23, embedded controller/keyboard controller (EC/KBC) 25, power supply circuit 26, and the like.

The CPU 11 is a processor for controlling the operations of the respective units in the computer 1. The CPU 11 executes an operating system loaded from the HDD 18 to the main memory 13 and various application programs including utilities that operate under the control of the operating system. These various application programs include a keyboard setting utility 110 to be described later. The CPU 11 executes a BIOS stored in the BIOS-ROM 17. The BIOS is a program for hardware control.

The north bridge 12 is a bridge device which connects the local bus of the CPU 11 and the south bridge 16. The north bridge 12 has a function of executing communications with the graphics accelerator 14 via a bus. The north bridge 12 incorporates a memory controller for controlling access to the main memory 13. The graphics accelerator 14 is a display controller for controlling the LCD 15 used as the display monitor of this computer. The graphics accelerator 14 generates a display signal output to the LCD 15 in accordance with the image data written in the VRAM 14A.

The south bridge 16 is a controller for controlling the respective devices on the PCI and LPC buses. The south bridge 16 is directly connected to the BIOS ROM 17, HDD 18, USB controller 19, sound controller 20, LAN controller 22, WLAN controller 23, and the like and has a function of controlling these units.

The HDD 18 is a memory device which stores various kinds of software and data. The USB controller 19 is a controller for executing communications with cable connected USB devices. The sound controller 20 is a sound source controller for controlling the loudspeaker 21. The LAN controller 22 and WLAN controller 23 are controllers for executing communications with external devices via a network.

The EC/KBC 25 is a one-chip microcomputer on which an embedded controller for power management and the keyboard controller for controlling the keyboard 28 and touch pad 29 are integrated. The EC/KBC 25 cooperates with the power supply circuit 26 to control the power supply from the battery 27 or an external AC power supply to the respective units. The EC/KBC 25 holds a determination table 251 to be described later.

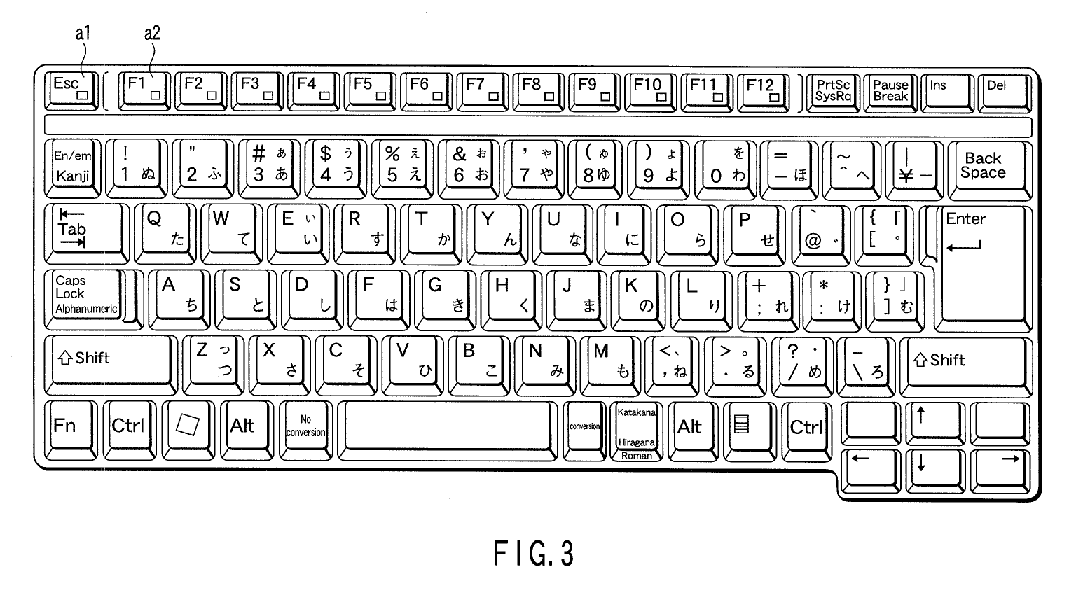

FIG. 3 shows an example of the key layout of the keyboard 28 in the computer 11 having the above arrangement. In FIG. 3, a hiragana [Japanese character] is printed on some of the keys, but such a character has nothing to do with the constitution of the present invention.

As shown in FIG. 3, the keyboard 28 of the computer 1 has a standard key layout called a 109 keyboard. The keyboard 28 has no specific hardware properties except being made compact by reducing the key pitch. Assume that a key a1 (ESC key) is a high-use-frequency key and a key a2 (F1 key) is a low-use-frequency key, due to the type of installed operating system. More specifically, a high-use-frequency key and a low-use-frequency key are adjacent to each other on the compact keyboard, and the user may erroneously press the key a2 instead of the key a1. That is, a key input error is highly likely to occur. In consideration of the above situation, there is provided a mechanism for flexibly providing an operation error preventing measure for adjacent keys. This point will be described in detail below.

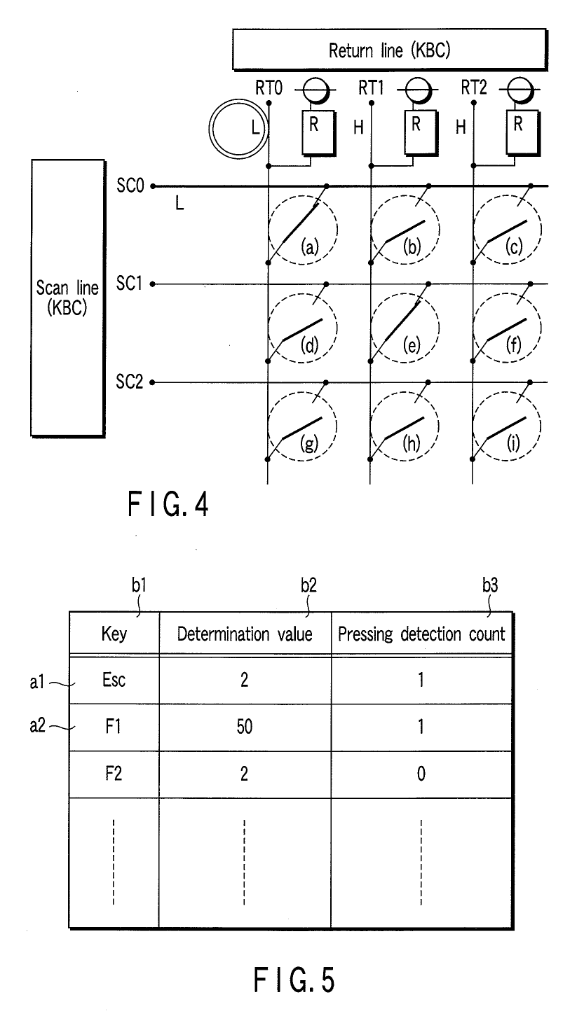

FIG. 4 is an exemplary view for explaining the principle of causing the EC/KBC 25 to monitor the state of each key on the keyboard 28.

The keyboard 28 has a wiring matrix made up of two types of lines, i.e., a plurality of scan lines and a plurality of return lines. Each key is assigned to one intersection between the two types of lines. The EC/KBC 25 makes the scan lines low one by one and confirms the states of all the return lines. If a pressed key is present, the corresponding return line is made low, thereby detecting that the corresponding key is kept pressed. This series of operations is called a scan.

This scan is done repeatedly, e.g., every 10 ms. When the EC/KBC detects the pressed state continuously twice during the scan, the EC/KBC determines that the key was pressed. The EC/KBC 25 of the computer 1 holds the determination table 251, so it can set the number of times of detection of the pressed state in a software manner. FIG. 5 shows an example of the determination table 251 held by the EC/KBC 25 of the computer 1.

As shown in FIG. 5, the determination table 251 has a key field b1, determination value field b2, and pressing detection count field b3. The key field b1 is an area which holds the identifier of each key. The EC/KBC 25 looks up and manages the determination value and pressing detection count of each key using the identifier as an index.

The determination value field b2 is an area which holds a reference value representing that key pressing is determined by a predetermined number of times of consecutive key pressing detection during the scan. The pressing detection count field b3 is an area which counts the number of times of consecutive key pressing detection during the scan.

As shown in FIG. 5, the determination value of the high-use-frequency key a1 (Esc key) is set to 2, and the determination value of the low-use-frequency key a2 (F1 key) is set to 50. If the user presses the keys a1 and a2 (although the user wants to press only the key a1), the pressing detection counts b3 of the keys a1 and a2 start to increment in 10 ms at maximum.

The values of the pressing detection count fields b3 of the keys a1 and a2 each increment to 2, 10 ms after the first incrementing operation. At this time, since the value of the key a1 has reached the determination value, and the EC/KBC 25 determines that the user pressed the key a1. On the other hand, the value of the key a2 has not reached the determination value. At this time, the EC/KBC 25 does not determine that the user pressed the key a2. The EC/KBC 25 determines that the user pressed the key a2 only if the user presses the key a2 continuously for 480 ms.

As described above, in the computer 1, the EC/KBC 25 holds the determination table 251. The sensitivity of each key on the keyboard 28 can be changed in a software manner. Software which is prepared for allowing the user to arbitrarily set the reference value of each key and held in the determination value field b2 of the determination table 251 is the keyboard setting utility 110.

The keyboard setting utility 110 can provide a user interface for causing the user to directly input a value to be held in the determination value field b2. However, for the sake of convenience, the keyboard setting utility 110 provides a user interface for allowing the user to designate a low input sensitivity key (here the key a2 [F1 key]). The EC/KBC 25 updates the determination table 251 held in it so as to change the reference value designated by this user interface in the range of, e.g., 2 to 50. For example, three choices (two or more) such as “high”, “medium”, and “slow” are prepared for each key, and the value such as “2”, “20”, and “50” may be set in accordance with the selection result.

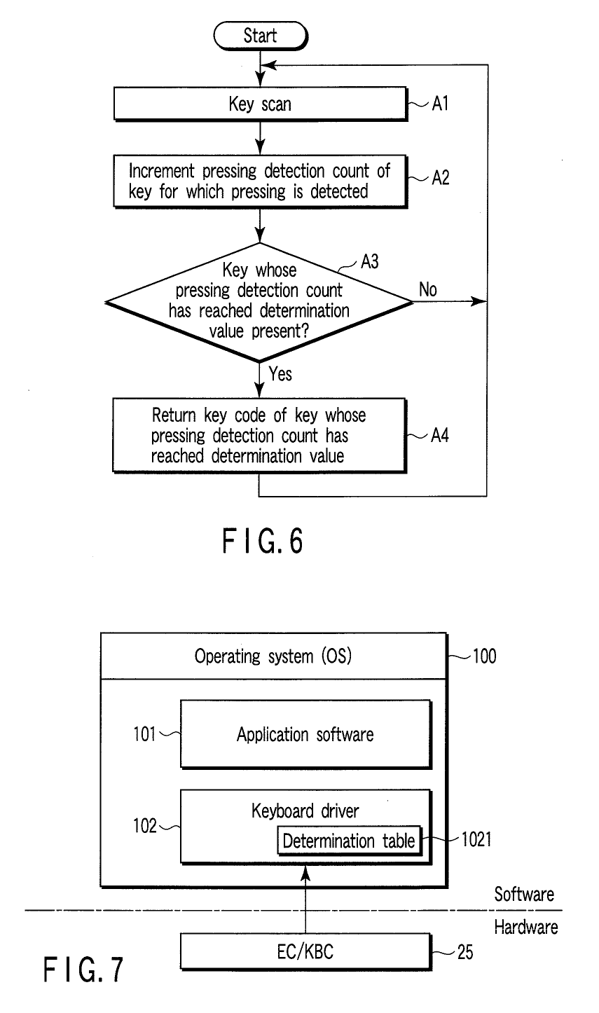

FIG. 6 is an exemplary flowchart showing the operation sequence of key pressing determination executed by the EC/KBC 25 of the computer 1.

The EC/KBC 25 performs a scan, e.g., every 10 ms (block A1) to increment the key pressing detection count of a key detected as a key in the pressed state (block A2). The EC/KBC 25 determines whether a key whose pressing detection count has reached a determination value is present (block A3). If such a key is preset (YES in block A3), the EC/KBC 25 determines that this key was pressed. The EC/KBC 25 returns the code of this key to a keyboard driver on the operating system serving as a host system or the BIOS (block A4).

As described above, the computer 1 can flexibly provide the operation error preventing measure for adjacent keys. Note that the electronic apparatus is implemented as a notebook computer and the KBC is mounted in the computer main body 2. However, the present invention is not limited to this. For example, the electronic apparatus can be implemented as an external keyboard incorporating the KBC.

### Second Embodiment

The second embodiment of the present invention will now be described below.

In the first embodiment, the EC/KBC 25 holds the determination table 251, and the sensitivity of each key on the keyboard 28 is changed in a software manner under the control of the EC/KBC 25. Conversely, according to the second embodiment, an EC/KBC 25 performs normal operation (i.e., a common reference is used for all keys to return key codes). The keyboard driver on the operating system serving as a host system or BIOS which receives a key code from the EC/KBC 25 controls to change the sensitivity of each key on a keyboard 28. FIG. 7 is an exemplary functional block diagram associated with key inputs of a computer 1.

The computer 1 receives the key code from the EC/KBC 25 using a keyboard driver 102 on an operating system 100. More specifically, the keyboard driver 102 executes control for changing the sensitivity of each key on the keyboard 28 in a software manner. The keyboard driver 102 transfers the received key code to an active application software 101.

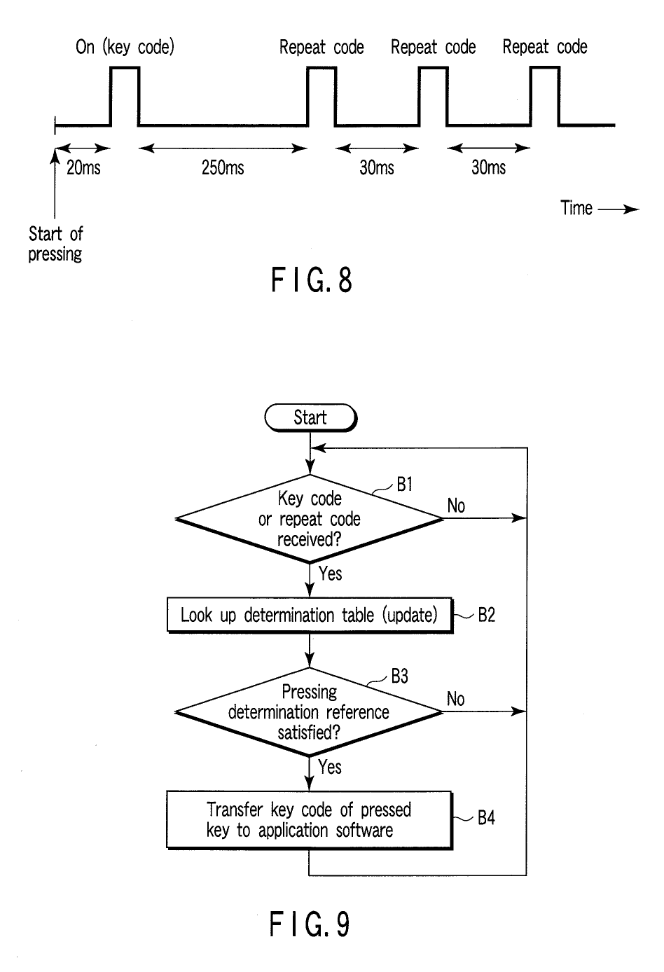

For this purpose, the keyboard driver 102 of the computer 1 of this embodiment holds a determination table 1021. The determination table 1021 corresponds to the determination table 251 held by the EC/KBC 25 of the first embodiment. The principle of outputting a key code by the EC/KBC 25 will be described with reference to FIG. 8.

When the user presses any key, the EC/KBC outputs the key code of this press detected key in 20 ms at maximum. When the user continuously presses this key, the EC/KBC 25 outputs a repeat code after 250 ms. The repeat code is a code for notifying that the key corresponding to the immediately preceding output code is kept pressed. Thereafter, the EC/KBC 25 outputs this repeat code every 30 ms.

The determination field of the determination table 1021 held by the keyboard driver 102 of the computer 1 holds the input count of this repeat code. The keyboard setting utility 110 of the computer 1 of this embodiment sets the values in the determination value field of the determination table 1021 held by the keyboard driver 102. The keyboard driver 102 counts the input count of the repeat code using the pressing detection count field of the determination table 1021.

When the determination values “0” and “9”, for example, are held in the high-use-frequency key a1 (Esc key) and the low-use-frequency key a2 (F1 key), respectively, the repeat code input count has been reached when the key code for the key a1 is input. The keyboard driver 102 immediately transfers the key code of the key a1 to the application software 101. On the other hand, as for the key a2, upon inputting the key code, the keyboard driver 102 transfers the key code of the key a2 after the elapse of 250 ms +30 ms×8=490 ms (the user must keep pressing the key a2 during this time).

FIG. 9 is an exemplary flowchart showing the operation sequence of key pressing determination executed by the keyboard driver 102 of the computer 1.

Upon receiving the key code or repeat code from the EC/KBC 25 (block B1), the keyboard driver 102 looks up the determination table 1021 (block B2). Upon receiving the repeat code, the keyboard driver 102 also updates the determination table 1021.

The keyboard driver 102 determines whether a key satisfying the pressing determination reference is present (block B3). If such a key is present (YES in block B3), the keyboard driver 102 transfers the key code of this key to the application software (block B4).

As has been described above, the computer 1 can flexibly provide an operation error preventing measure for adjacent keys.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An electronic apparatus comprising:
a plurality of keys;
a monitoring unit configured to repeatedly monitor whether each of the plurality of keys is in a pressed or a non-pressed state;
a setting unit configured to set a separate reference value for determining whether each of the plurality of keys will be deemed to have been intentionally pressed; and
a determination unit configured to determine that a given key has been intentionally pressed when the number of pressed states continuously detected by the monitoring unit for the given key reaches the reference value for the given key.

2. The electronic apparatus according to claim 1, wherein the setting unit comprises a user interface configured to permit a user to select a first value or a second value larger than the first value as a reference value for a key.

3. The electronic apparatus according to claim 2, wherein the user interface comprises a designating unit configured to permit a user to designate a low input sensitivity key, and a detecting unit configured to select the second value as the reference value for the designated low input sensitivity key.

4. The electronic apparatus according to claim 1, wherein the setting unit comprises a user interface unit configured to permit a user to select one of not less than two different values as the reference value for a key.

5. An electronic apparatus comprising:
an input unit configured to input a key code representing that one of a plurality of keys is pressed or a repeat code representing that the key indicated by the key code remains pressed;
a setting unit configured to set, as a reference value for determining whether each of the plurality of keys will be deemed to have been intentionally pressed, the number of repeat codes to be input by the input unit for each key; and
a determination unit configured to determine, when the input unit inputs a key code and the number of repeat codes reaches the reference value set by the setting unit, that a key represented by the key code is pressed.

6. The electronic apparatus according to claim 5, wherein the setting unit comprises a user interface configured to permit a user to select a first value or a second value larger than the first value as the reference value.

7. The electronic apparatus according to claim 6, wherein the first value is zero, and when the input unit inputs a key code of a key for which the first value is set, the determination unit is configured to determine that a key represented by the key code at this time was pressed.

8. The electronic apparatus according to claim 6, wherein the user interface comprises a designating unit configured to permit a user to designate a low input sensitivity key, and a detecting unit configured to select the second value for the designated key.

9. The electronic apparatus according to claim 5, wherein the setting unit comprises a user interface unit configured to permit a user to select one of not less than two different values as the reference value.

10. A key pressing determination method for an electronic apparatus comprising a plurality of keys and a monitoring unit configured to repeatedly monitor states of the plurality of keys at a predetermined period, the method comprising:
setting, as a reference value for determining whether each of the plurality of keys will be deemed to have been intentionally pressed, the number of pressed states continuously detected by the monitoring unit; and
determining that a user intentionally pressed a given key when the number of pressed states continuously detected by the monitoring unit for the given key reaches the set number of pressed states.

11. A key pressing determination method for an electronic apparatus comprising a input unit configured to input a key code representing that one of a plurality of keys is pressed or a repeat code representing that the key indicated by the key code remains pressed, the method comprising
setting, as a reference value for determining whether each of the plurality of keys will be deemed to have been intentionally pressed, the number of repeat codes to be input by the input means for each key; and
determining, when the input unit inputs a key code and the number of repeat codes reaches the reference value, that a key represented by the key code has been intentionally pressed.
